(19) United States
(12) Patent Application Publication
(10) Pub. No.: US 2024/0169130 A1
(43) Pub. Date: May 23, 2024

(54) METHOD FOR AUTOMATED INTERPRETATION OF PLT DATA THROUGH THE INVERSE METHOD WITH SMOOTHNESS LINK

(71) Applicant: PETRÓLEO BRASILEIRO S.A. - PETROBRAS, Rio de Janeiro (BR)

(72) Inventor: LUCIANO DOS SANTOS MARTINS, Rio de Janeiro (BR)

(21) Appl. No.: 18/307,655

(22) Filed: Apr. 26, 2023

(30) Foreign Application Priority Data
Nov. 18, 2022 (BR) 10 2022 023461 2

(51) Int. Cl. G06F 30/28

(52) U.S. Cl. CPC G06F 30/28

(57) ABSTRACT

The present invention is applied in the interpretation and processing of data from the PLT (Production Logging Tool) tool that are obtained during a cased well formation test. The present invention reduces the randomness of interpretation using an inverse method that does not require user zoning. For this, it is assumed that the function is increasing (valid in the vast majority of cases, otherwise there would need to be a cross flow) and that the solution is smooth, which is valid for the discretization used by this invention.

### FIELD

The present invention pertains to the field of oil wells. More specifically, this invention relates to methods for automatically interpreting data obtained by a PLT (Production Logging Tool).

### BACKGROUND

A profiling cable (string) typically contains several sensors for monitoring all steps of the process. As an example, temperature, pressure, capacitance and flow rate sensors can be mentioned, the latter performing an indirect measurement of flow rate through the rotation of a spinner. The PLT (Production Logging Tool) is a cable tool used during the production operation of an oil well, which provides a better understanding of the reservoir during the flow step, highlighting its use for zoning the contribution of production in heterogeneous formations. Other typical uses of the PLT include diagnosing perforation, cross flow, or water and/or gas cone problems, among others.

The main profile acquired by the PLT is the spinner rotation velocity. With this data obtained during several passes both ascent and descent, together with information on the well design, cable speed, fluid properties, and assuming a laminar flow model, it is possible to obtain the flow rate per subsurface depth.

PLT data are usually very noisy due to uncertainties related to heave, tool stability, flow regime, etc. The interpretation of this type of data is very dependent on the user input, and may have divergent results if the data is delivered to two people to carry out the analysis independently.

According to the State of the Art, the user needs to define the zones in which he believes there is a greater flow contribution, which is limited to the visual perception of that user. Such a method is a direct analysis, and a wrong zoning can provide a result that is incompatible with the acquired data, which may result in a solution that is not consistent with reality. The resolution also does not have a uniform discretization, which is determined according to the user zoning.

The international publication WO2021073776A1, entitled “Event characterization using hybrid DAS/DTS measurements”, discloses a method for determining the presence and/or extent of an event, comprising determining a plurality of temperature characteristics of a temperature detection signal, determining one or more frequency domain characteristics of an acoustic signal and using at least one temperature characteristic of the plurality of characteristic temperatures and at least one frequency domain characteristic of one or more frequency domain characteristics to determine the presence and/or extension of the event in one or more places. The method for determining the presence and/or extent of an event comprises determining a plurality of temperature characteristics from a temperature detection signal, determining one or more frequency domain characteristics of an acoustic signal, and using at least one temperature characteristic of the plurality of temperature characteristics and at least one frequency domain characteristic of one or more frequency domain characteristics to determine the presence and/or extent of the event at one or more places. The plurality of temperature characteristics may comprise, for example, a derivative of temperature with respect to depth.

Patent GB2494559B, entitled “Method for interpretation of distributed temperature sensors during wellbore treatment”, refers to a method for determining the flow distribution in a formation, having a wellbore formed therein, and includes the steps of positioning a sensor within the wellbore, wherein the sensor generates a feedback signal representing at least one of a temperature and a pressure measured by the sensor, injecting a fluid into the wellbore and into at least a portion of the formation adjacent to the wellbore sensor, shutting in the wellbore for a predetermined shut-in period, generating a simulated model representing at least one of the simulated temperature characteristics and simulated pressure characteristics of the formation during the shut-in period, generating a data model representing at least one of the actual temperature characteristics and actual pressure characteristics of the formation during the shut-in period wherein the data model is derived from the feedback signal, comparing the data model with the simulated model, and adjusting the simulated model parameters to substantially match the data model.

Both above-mentioned documents of prior art propose methods that use DTS (Distributed Temperature Sensing) and DAS (Distributed Acoustic Sensing); i.e., continuous temperature and acoustic signal measurements. Such methods are suitable only during periods of injection or shut-in, having greater uncertainty in scenarios where fluids that react with the formation are injected.

Therefore, the state of the art lacks methods for optimized and automatic smoothing of the curve obtained during the production step, where the PLT is used and where there is already a thermal balance between the well and the formation.

### SUMMARY OF THE INVENTION

The present invention aims at addressing to a new method to obtain the interval contribution of oil well flow rates. The results obtained make the process more automatic and less interpretive, forcing a better fit of the model to the data, which is not always obtained by a commercial software such as Emeraude (KAPPA Engineering).

The method presented in this invention eliminates the user influence in the interpretation of the data and makes the process more agile. The proposed solution is able to provide a higher resolution to the results, because the discretization performed is uniform, and the results between different wells and data of different scales (compared to a well log and which have a higher resolution) can be more comparable with each other, by attenuating the interpreter variable (i.e., the influence of the interpreter) and allowing a better comparison between the flow data with conventional profiles. This type of solution also allows eliminating the pre-processing phase, seeking the model that fits the raw curves instead of the pre-processed ones, further optimizing the process.

### BRIEF DESCRIPTION OF THE DRAWINGS

The present invention will be described below with reference to its typical embodiments and the attached drawings, in which:

FIG. 1 is a representation of the parabolic velocity profile in a laminar flow with a cylindrical tube, in accordance with the present invention;

FIG. 2 is a representation of a spinner, adapted from Dynamic Data Analysis v4.12.02 (© KAPPA 1988-2011);

FIG. 3A is a representation of a perforated well in production, adapted from Dynamic Data Analysis v4.12.02 (© KAPPA 1988-2011);

FIG. 3B is a representation of data acquired by the spinner in the well of FIG. 3A, adapted from Dynamic Data Analysis v4.12.02 (© KAPPA 1988-2011);

FIG. 4 is a representation of a PLT profile calibration curve for obtaining fluid velocity, adapted from Dynamic Data Analysis v4.12.02 (© KAPPA 1988-2011);

FIG. 5 is a representation of the apparent velocity obtained from the spinner versus the average velocity in accordance with the present invention;

FIG. 6 is a representation of the correction factor applied to the apparent velocity obtained by the spinner, adapted from Dynamic Data Analysis v4.12.02 (© KAPPA 1988-2011);

FIG. 7A is a plot of the velocity data obtained by the spinner, visualized in the Emeraude software, in accordance with the present invention;

FIG. 7B is the data fit of FIG. 7A performed by the Emeraude software, in accordance with the present invention;

FIG. 7C is a plot of velocity data obtained by the spinner with a different user adjustment compared to FIG. 7A, in accordance with the present invention;

FIG. 7D is the adjustment of the data of FIG. 7C performed by the Emeraude software, in accordance with the present invention;

FIG. 8A is a plot of the velocity data obtained by the spinner, visualized in the PLTinterp software, in accordance with the present invention;

FIG. 8B is the adjustment of the data of FIG. 7C performed by the PLTinterp software, in accordance with the present invention;

FIG. 9 is an exemplary flowchart of a preferred embodiment of the method in accordance with the present invention;

FIG. 10 is a comparison of the interval contribution per zone by the proposed method and a method similar to the Emeraude software using the response of the PLTinterp software as a model for the zoning;

FIG. 11 is a comparison between the conventional method and the inverse method of the present invention for well-1;

FIG. 12 is a comparison between the conventional method and the inverse method of the present invention for well-2;

FIG. 13 is a comparison between the conventional method and the filtering method of the present invention for well-1;

FIG. 14 is a comparison between the conventional method and the filtering method of the present invention for well-2;

FIG. 15 is a detail of the data obtained for well-2, in accordance with the present invention.

### DETAILED DESCRIPTION OF THE INVENTION

Specific embodiments of the present disclosure are described below. In an effort to provide a concise description of these embodiments, all features of an actual implementation may not be described in the specification. It should be appreciated that, in the development of any actual implementation, as in any engineering or design project, numerous implementation-specific decisions must be made to achieve the developers' specific goals, such as compliance with system- and business-related constraints, which can range from one implementation to another. In addition, it should be appreciated that such a development effort may be complex and time consuming, but would nevertheless be a design and manufacturing routine undertaking for those of ordinary skill having the benefit of this disclosure.

In the theory of fluid mechanics, the Reynolds number is an important parameter to define the flow regime. In a simplified way, this is a dimensionless term of the ratio between the inertial and viscous forces, in which its value determines whether the flow regime is laminar, transitional, or turbulent, according to equation 1 below:

$$Re = \frac{ρ {V}_{avg} D}{μ} \qquad ( 1 )$$

where Re is the Reynolds number; ρ is the density in kg/m³; V_{avg} is the average velocity in m/s; D is the characteristic length in m; and μ is the viscosity of the fluid in cP.

Typical oil wells are 8 to 12 inches in diameter (from 0.2032 to 0.3048 meters), with fluids with an approximate density of 0.8 g/cm³, viscosity of 1 cP and maximum average velocities around 150 m/min during a Cased Well Formation Test (TFR). This gives Re<2000 which, according to Table 1 below, valid for flows in cylindrical tubes of diameter D, justifies a laminar flow model to evaluate the problem in question:

TABLE 1

| Flow Regime | Reynolds Number (Re) |
|---|---|
| Laminar Regime | Re < 2300 |
| Transitional Regime | 2900 < Re < 2300 |
| Turbulent Regime | Re > 2900 |

Knowing that in a laminar regime the velocity field does not vary with time, and using Newton's second law (F=m·a), mass conservation law, and the boundary conditions of zero velocity at the edges, we have that for a cylindrical tube the velocity profile is given by:

$$V ( r ) = {V}_{max} ( 1 - \frac{{r}^{2}}{{R}^{2}} ) \qquad ( 2 )$$

where V(r) is the radial velocity profile; Vₘₐₓ is the maximum flow velocity; r is the radius measured from the center of the cylinder; and R is the radius of the cylinder.

More details of the deduction can be seen in “Jaroslav Stigler, Analytical Velocity Profile in Tube for Laminar and Turbulent Flow, Engineering Mechanics, Vol. 21, 2014, No. 6, p. 371-379”, not being addressed to herein.

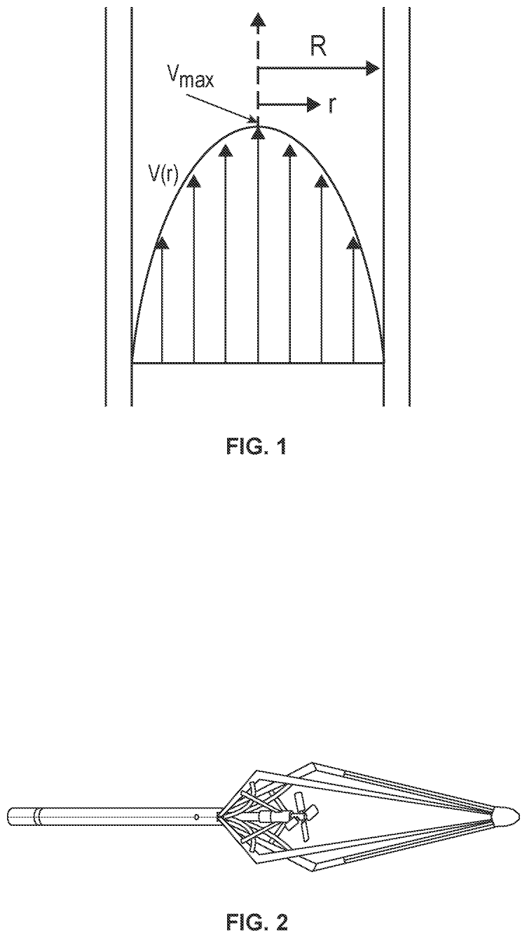

This is a parabolic velocity profile that is best visualized in FIG. 1. With the velocity profile known, the flow rate can be determined simply by the integral of the area seen in equation 3:

$$q ( z ) = {\int }_{A} V ( r , z ) dA = \frac{π {R}^{2}}{2} {V}_{max} ( z ) \qquad ( 3 )$$

where q(z) is the well flow for a well depth z; Vₘₐₓ is the maximum flow velocity; V(r,z) is the radial velocity profile for each depth z; A is the cross-sectional area of the well; Vₘₐₓ(z) is the maximum flow velocity for depth z; and R is the radius of the cylinder.

Equation 3 provides the flow rate q(z) at each depth z of the oil well. One of the objectives of the PLT profile is to obtain the contribution of the interval flow rate and, for that, the total flow rate is needed. The main data of the PLT profile is the spinner rotation velocity (FIG. 2), acquired mainly during a reservoir flow step. A spinner is an element lowered into the well by means of a cable and capable of rotating around a shaft according to the difference in relative velocity between the cable and the well flow. Although the flow velocity is difficult to measure directly, the spinner rotation velocity is easily obtained during several passes with different cable descent and ascent speeds for calibration and increasing the signal-to-noise ratio.

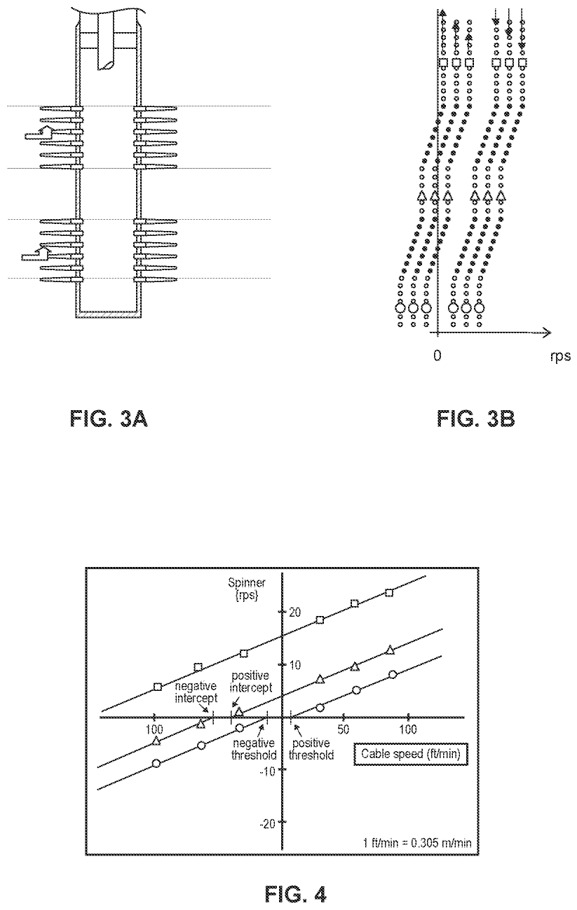

Referring to FIGS. 3A-B, a schematic of the acquired spinner velocity profile is illustrated. FIG. 3A represents a perforated well in production, whereas FIG. 3B represents the data acquired by the spinner during several ascent and descent passes in revolutions per second (rps).

During a static period, the spinner rotation velocity will be proportional to the cable speed. During the flow, it will be proportional to the cable speed and the fluid velocity. To obtain the fluid velocity, it is necessary to cross-plot the spinner rotation by the cable speed for each depth, as shown in FIG. 4, which presents the PLT profile calibration curve for obtaining the fluid velocity, in which the points in blue are equivalent to those acquired during a static period (fluid velocity=0).

The slope of the curve and the threshold are dependent on the characteristics of the spinner and the fluid. As normally data are acquired in single-phase flow, it is assumed that the fluid velocity will be a sum or subtraction ratio between the intercept and the threshold.

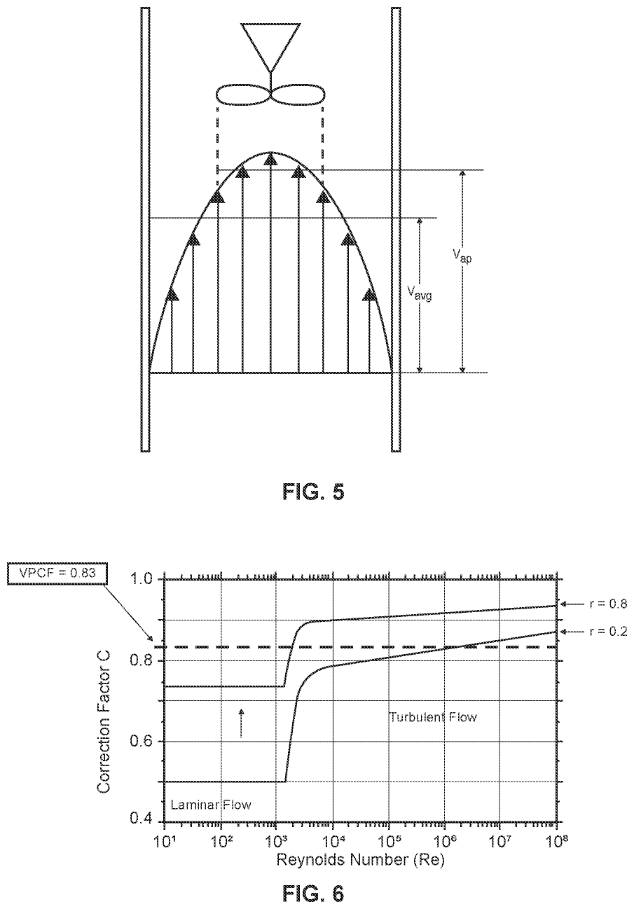

As can be seen in FIG. 5, the fluid velocity obtained is an apparent velocity (Vₐₚ). This is because the spinner is influenced by only a small part of the velocity field. In FIG. 5, Vₐₚ is the apparent velocity measured in the spinner and V_{avg} is the average true velocity of the flow. To obtain the true flow rate, it is necessary to obtain the maximum flow velocity from the apparent velocity Vₐₚ. The average velocity Va_{vg} can be determined by the following equation 4:

$${V}_{avg} = \frac{{\int }_{A} V ( r ) dA}{{\int }_{A} dA} = \frac{2}{{R}^{2}} {\int }_{0}^{R} V ( r ) vdr \qquad ( 4 )$$

where V_{avg} is the average velocity; A is the cross-sectional area of the well, R is the radius of the well; and V(r) is the radial velocity profile.

Replacing equation (2) in (4), we have:

$${V}_{avg} = \frac{2 {V}_{max}}{{R}^{2}} {\int }_{0}^{R} ( 1 - \frac{{r}^{2}}{{R}^{2}} ) rdr = \frac{2 {V}_{max}}{{R}^{2}} {\int }_{0}^{R} ( r - \frac{{r}^{3}}{{R}^{2}} ) dr$$

$${V}_{avg} = {\frac{2 {V}_{max}}{{R}^{2}} [ \frac{{r}^{2}}{2} - \frac{{r}^{4}}{4 {R}^{2}} ]}_{0}^{R} = \frac{2 {V}_{max}}{{R}^{2}} [ \frac{{R}^{2}}{2} - \frac{{R}^{4}}{4 {R}^{2}} ]$$

$${V}_{avg} = \frac{2 {V}_{max}}{{R}^{2}} [ \frac{2 {R}^{2} - {R}^{2}}{4} ] = \frac{{V}_{max}}{2}$$

Therefore, Vₘₐₓ=²V_{avg}. To obtain the apparent velocity Vₐₚ, simply replace the well radius R by the spinner radius Rₛ in (4), as seen below:

$${V}_{ap} = \frac{2 {V}_{max}}{{R}_{s}^{2}} {\int }_{0}^{{R}_{s}} ( 1 - \frac{{r}^{2}}{{R}^{2}} ) rdr = \frac{2 {V}_{max}}{{R}_{s}^{2}} {\int }_{0}^{R} ( r - \frac{{r}^{3}}{{R}^{2}} ) dr$$

$${V}_{ap} = {\frac{2 {V}_{max}}{{R}_{s}^{2}} [ \frac{{r}^{2}}{2} - \frac{{r}^{4}}{4 {R}^{2}} ]}_{0}^{{R}_{s}} = \frac{2 {V}_{max}}{{R}_{s}^{2}} [ \frac{{R}_{x}^{2}}{2} - \frac{{R}_{s}^{4}}{4 {R}^{2}} ]$$

$${V}_{ap} = {V}_{max} [ 1 - \frac{{R}_{s}^{2}}{2 {R}^{2}} ] ⇒ {V}_{max} = \frac{2 {R}^{2}}{( 2 {R}^{2} - {R}_{s}^{2} )} {V}_{ap}$$

from which equation 5 results:

$${V}_{max} = \frac{2 {R}^{2}}{( 2 {R}^{2} - {R}_{S}^{2} )} {V}_{ap} . \qquad ( 5 )$$

This occurs because the spinner is sensitive to only one part of the velocity profile, obtaining a value closer to Vₘₐₓ, as seen in FIG. 5. Therefore, using equation 5, the maximum velocity is obtained from the velocity read by the spinner, Vₐₚ, and consequently, the well flow rate by replacing Vₘₐₓ in equation 3.

Referring to FIG. 6, adapted from Dynamic Data Analysis v4.12.02 (© KAPPA 1988-2011), in which VPCF is the correction factor applied to Vaₚ and r is the ratio between the diameter of the spinner helix and the inner diameter of the cylinder, it can be seen that the correction factor for laminar flows applied to the apparent velocity Vₐₚ is constant for a given well versus spinner configuration, represented by r. That is, under these conditions, the correction factor is independent of velocity and Reynolds number, a result that agrees with equation 5. Therefore, it is clear that the total flow rate q(z) can be determined for each depth through the data obtained by the PLT. Thus, from equations 5 and 3, the flow rate versus Vₐₚratio is given only by a multiplicative constant.

The main product of the PLT is the individualization of the producing areas from the Vₐₚ data. In this disclosure, three methods are presented to obtain this result, one commercial and two developed by the inventor. All methods assume that the total flow rate q(z) obtained at a given well depth zₖ can be given by:

$$q ( {z}_{k} ) = {\sum }_{i = 0}^{k} \frac{Δ {q}_{i}}{Δ {z}_{i}} Δ {z}_{i} {\to }^{\begin{matrix}lim Δ x - 0 \\ lim k - ∞\end{matrix}} {\int }_{{z}_{1}}^{{z}_{k}} {q}^{′} ( z ) dz \qquad ( 6 )$$

where z is the well depth; q(zₖ) is the total flow rate at depth k; and q′ (zₖ) is the derivative of the flow rate with respect to z.

### Business Method

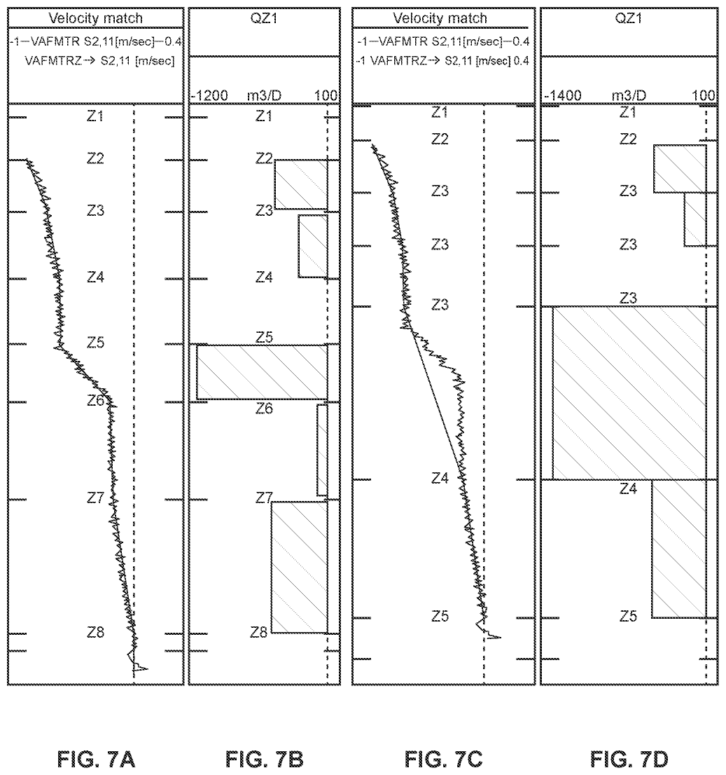

This method is the conventional method of the Emeraude program and common in the State of the Art, presented here for comparison purposes. It consists of dividing the apparent velocity curve into discrete regions. The user provides as input the zones that have no flow and the program solves the problem respecting the user input. The disadvantage of this method is that it is very dependent on the user's perception, which can lead to a layered model that does not fit the original data, as can be seen in FIGS. 7A-7D, in which plots in FIG. 7A and FIG. 7C correspond to the total velocity obtained by the spinner (red). The final model obtained according to the user's zoning are the blue bars represented in FIG. 7B and FIG. 7D. The calculated response for the model obtained in FIG. 7B and FIG. 7D is represented by the green curve in FIG. 7A and FIG. 7C. Note that in FIG. 7C, the model response obtained (green) according to user zoning does not resemble the original data (red) in the central region.

### Filtering Method

In this approach, q′ (zₖ) is obtained by simply deriving the total cumulative flow rate curve; however, a filtering treatment will be necessary to attenuate the noise. Thus, there is no guarantee of a link between the neighbors in the final model. As an input parameter, there is the frequency window for filtering.

Inverse Method with Smoothness Regularization

In this approach, a well is divided into several intervals from z₁ to zₙ. For each depth z₁, there is an associated value of the parameter p₁ forming pairs (z₁,p₁). The direct problem consists of: given a model [(z₁,p₁), (z₂,p₂), . . . , (zₙ,pₙ)], calculate q(z,p). The inverse problem aims at determining the parameters (p₁, p₂ , . . . , pₙ) that adjust the data acquired at each point q(zₖ). For this, an objective function with smoothness regularization is used; that is:

θ∥d-ƒ(p)∥²+w∥ĉp∥²

where θ is the objective function to be minimized; d is the acquired data (for the problem in question, the apparent velocity, but it could be the raw spinner rotation data, or even other profiles along with the spinner rotation), f(p) is the data calculated from the model (in this case, the interval flow rate, which is the final objective), w is the weight between the data adjustment and the regularization, and σp is the smoothness regularization [(p₂-p₁), (p₃-p₂), . . . , (pₙ-pₙ-1)].

Several optimization methods exist to solve the problem of equation 7. For example, there can be mentioned the Gradient Descent (GD), Gauss-Newton (GN) and Levenberg-Marquardt (LM) methods, the latter being the one that best suits the purposes of the present invention. As methods are well known in the literature, for example, from The Levenberg-Marquardt algorithm for nonlinear least square curve-fitting problems (Henri P. Gavin, September/2020), they will not be discussed in detail herein.

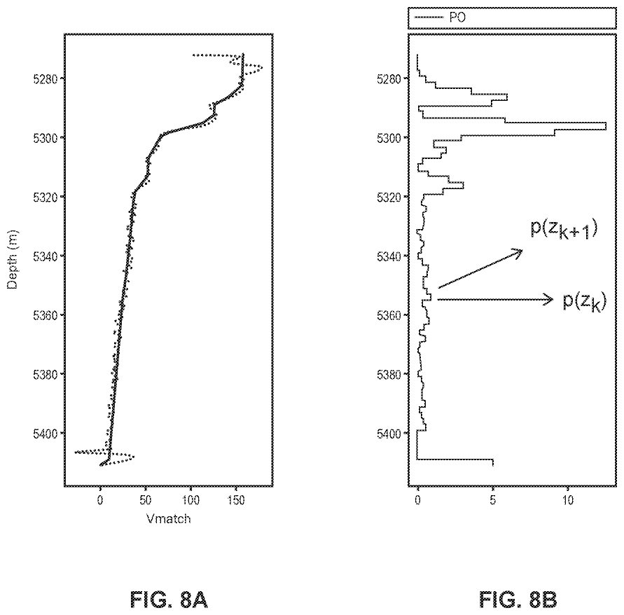

As an input parameter we have the number of parameters, an initial model and the weight w. The thickness of the discretization is also chosen, usually between 1 m and 2 m. The discretization does not change the result, but rather its resolution. The more discretized, the greater the computational effort to obtain the result. In addition, it is important to choose a discretization that is greater than the acquired data frequency. All these points must be considered by the operator when choosing the discretization thickness. A visual idea of the solution to this problem can be seen in FIGS. 8A-8B.

PLTinterp represents an interface and algorithm developed by the inventor. In FIG. 8A, the points are the original velocity (Vₐₚ, but as seen, the relationship of Vₐₚ with Vₘₐₓ and V_{avg} is just a multiplicative constant in the case of laminar flow) and the continuous curve is the velocity obtained by the model in FIG. 8B. FIG. 8B is the parameter model obtained by the inverse method providing only the weight parameter w. This method ensures a model that globally adjusts the data, ensuring a link between the same.

There is also the need of convergence criteria, which can be the number of interactions, convergence in the parameter space, and/or error in the model space, without being limited to these.

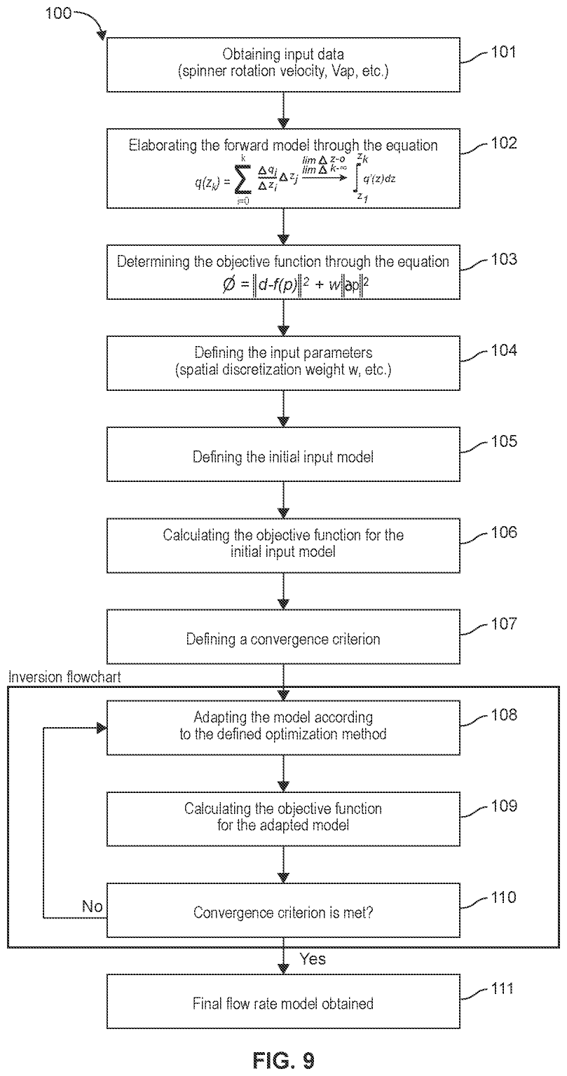

In summary, based on the disclosure above and with reference to FIG. 9, the preferred embodiment of the method 100 of the present invention can be defined as having the following steps:
101: Input data, such as the spinner rotation velocity, Vₐₚ, and others, are obtained by the sensors;
102: A Forward model is elaborated through equation 6; that is, the spinner rotational velocity response is obtained from the interval flow rates in a manner conventional in the art;
103: The objective function of the problem is determined through equation 7;
104: Input parameters such as spatial discretization and weight w are defined;
105: An initial input model is defined (for example, there can be used the model obtained by the filtering method);
106: The objective function is calculated for the initial input model defined in step 105;
107: At least one convergence criterion is defined (for example: number of iterations, and/or convergence in parameter space, and/or error in model space, etc.);
108: The initial input model is adapted according to the chosen optimization method (for example: Descent Gradient, Gauss-Newton, Levenberg-Marquardt etc.);
109: A new objective function is calculated for the adapted model in step 108;
110: A check is made whether the at least one convergence criterion is met (for example, by comparing the calculated result with the convergence criterion). If so, the final flow rate model is obtained (step 111) and the method ends. Otherwise, the method returns to step 108, except that instead of using the initial model defined in step 105 again, the model from step 108 is adapted again.

Steps 108, 109, and 110 constitute the flowchart of the inverse method proposed herein using an objective function as described in equation (7) and its optimization as earlier mentioned. These steps are repeated until the convergence criterion is met.

### Presentation and Discussion of Results

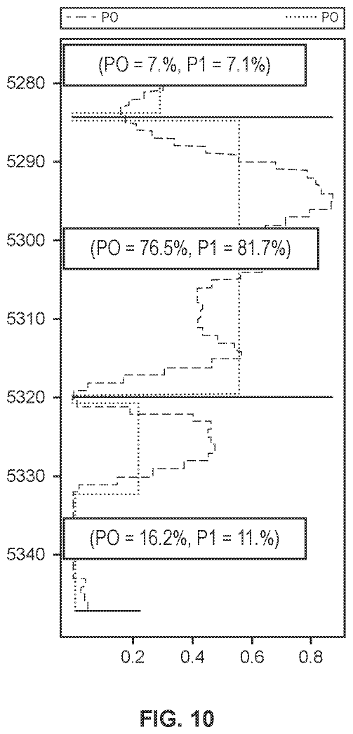

In this section, the results referring to the filtering and Inverse method with smoothness regularization in two different wells will be compared with the conventional Emeraude method obtained in a previous interpretation. For comparison purposes, the results obtained from the commercial software were normalized by a multiplicative constant that relates the apparent velocity Vₐₚ and the flow rate q(z). The validation of the inverse method algorithm has already been carried out by comparing the interval contribution by zone percentage with a similar methodology of the commercial software (FIG. 10), presenting very close values.

### Results of the Inverse Method

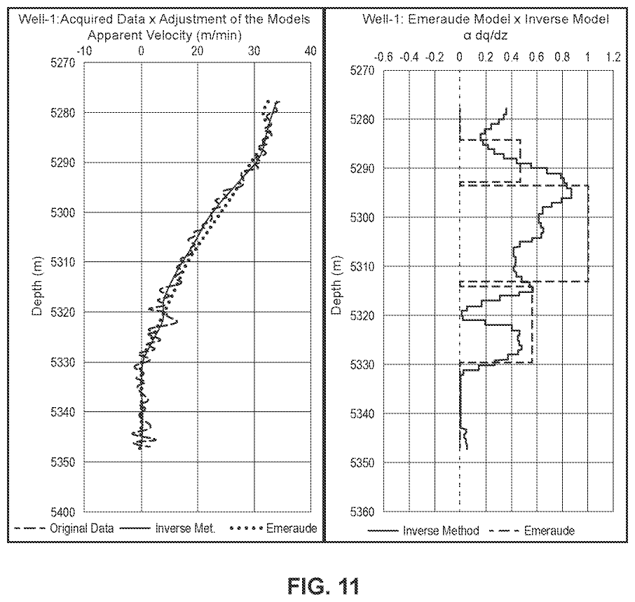

In this method, the developed algorithm seeks an increasing global solution with smoothness link. This allows high frequency noises not to generate a false influx zone or influence your model's response locally. In FIG. 11, there is a comparison of the models obtained by Emeraude and the Inverse Method, with their respective adjustments for a well called Well-1.

It is observed that with the commercial software it is necessary to provide the null zones; that is, with dq/dz=0. This interpretation turns out to be visual and, in this example, it is verified that a good fit at the base (between the depths of 5330 m and 5315 m) compromises a good fit towards the top (between the depths of 5315 m and 5295 m).

In the inverse method, the thickness of the discretization and the weight between the data adjustment and the regularization are provided. This result is obtained automatically without any additional user input. The result of the inverse method soon points to a different initial interpretation, identifying zones favorable to the flow between the depths of 5332 m to 5320 m and from 5320 m to 5285 m.

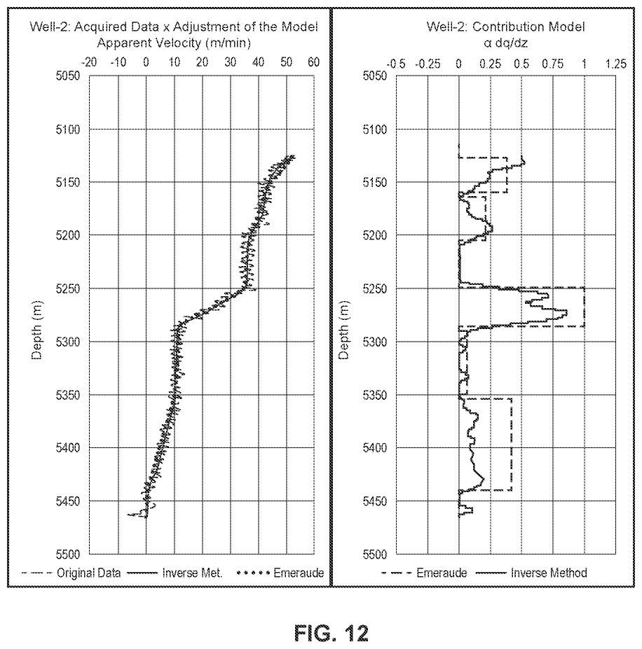

FIG. 12 illustrates the test for another exemplary well, called well-2. Although a greater correlation can be observed between the model obtained by Emeraude and the inverse method of the present invention, the inverse method results in greater resolution, being able to capture details that would not be considered by the conventional method. This result will be discussed in more detail later.

### Results Filtering Method

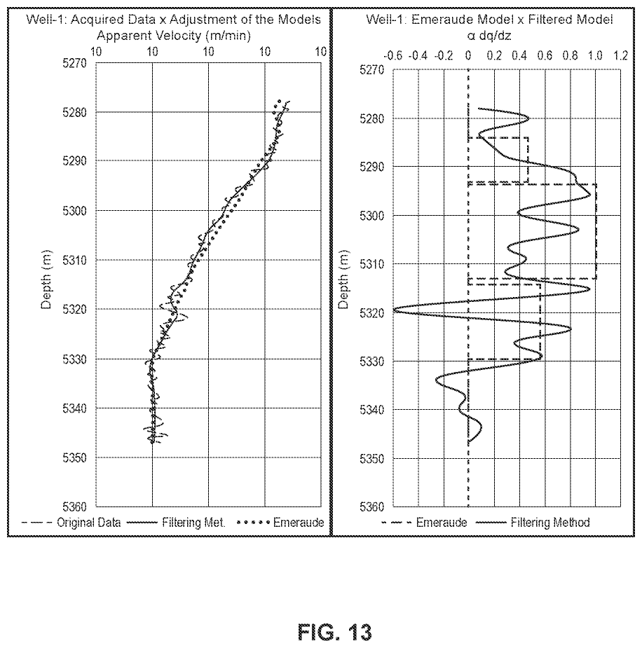

Filtering was performed in the frequency domain with a different window for each well. The main objective is to attenuate the tidal effect that is present in all data before applying the derivative, as this operation tends to amplify high frequency noise. FIG. 13 compares the result provided by Emeraude with a simple derivative of the filtered data for Well-1. As can be seen, the filtering method of the invention provides greater variability in the values, which can assume negative values, which suggests zones of influx. This is because the derivative is strongly affected by noise, and it is not possible to force an increasing function as in the case of the inverse method. Obviously, the filtered data fits the original data because it is simply a filter.

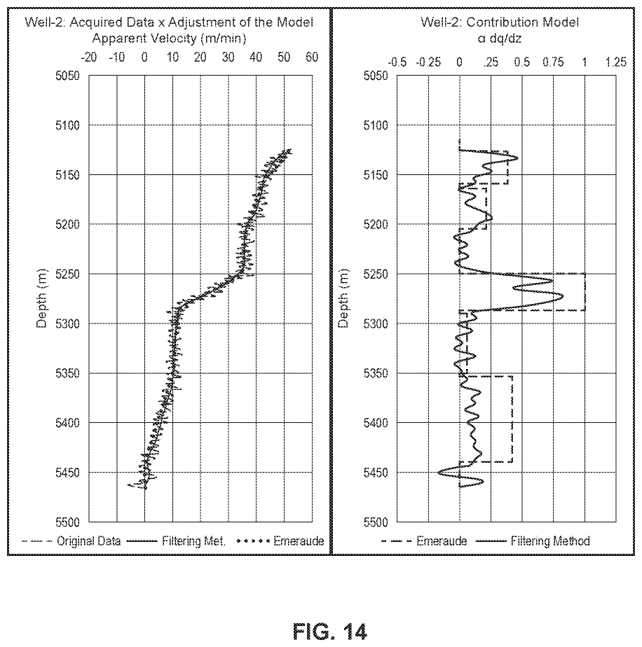

Next, in FIG. 14, there is the result obtained by the filtering method for Well-2. It can be observed that the result obtained by the filtering method is very similar to the inverse method (FIG. 12). This occurs because the original data has little noise, not harming the final model obtained.

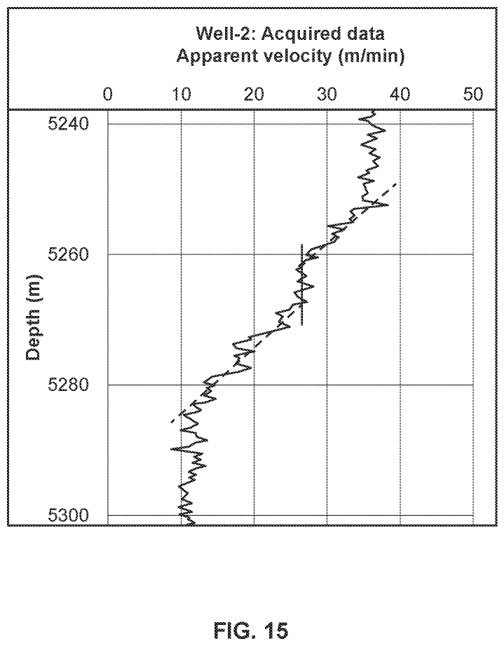

For Well-2, it is observed that both the inverse method and the filtering method present a different feature between the depths of 5250 m and 5300 m in relation to the conventional model obtained by Emeraude. Tidal noise is not justified, as in the inverse method there is less exposure to this type of problem, and in the filtering method there is filtering trying to minimize this effect. As illustrated in FIG. 15, when viewing the original data in more detail, a feature is observed that really indicates a differentiated flow zone in this interval, more specifically in the vicinity of the depth of 5260 m.

### Comparison of Adjustments of the Three Methods

In Table 2 below, there is a comparison of the global adjustment of the three methods (conventional, inverse, filtering) with the original data through the root mean square (rms), considering equation 8:

$$RMS = \frac{1}{n} {\sum }_{i = 1}^{n} {( {d}_{i} - {f}_{i} ( p ) )}^{2} \qquad ( 8 )$$

where n is the total number of parameters; d₁ is the data obtained at depth z₁; and f₁(p) is the result obtained by the method in question for depth z₁.

TABLE 2

| | Conventional | Inverse | Filtering |
|---|---|---|---|
| Well | method (Emeraude) | method | method |
| Well-1 | 1.68 | 0.68 | 0.56 |
| Well-2 | 1.90 | 1.14 | 1.30 |

The values in Table 2 indicate how much the response of the flow rate model obtained is similar to the original data. A rms of zero is not ideal as the data is noisy, and a very high rms could mean that your model does not explain the acquired data well. Table 2 clearly shows that the model obtained by the inverse and filtering method has lower rms. This difference is due to the different approach for solving the problem, providing models that are more consistent with the acquired data. As the filtering method is obtained directly from the apparent velocity Vₐₚ, a better fit is expected as in the case of Well-1. However, filtering can always present edge problems due to the frequency window and the fact that the original function is not periodic, in addition to not dealing with noise, which can cause an effect similar to overfitting. This means that in Well-2 the best overall fit is for the inverse method.

### CONCLUSIONS

Upon comparing the three methods for individualizing production zones, the one with the greatest influence from the user is Emeraude. Wrong zoning can generate a result that does not completely match the original data, providing a wrong representation of the dynamic model.

In turn, the inverse and filtering methods present better results. Differences between these methods occur when the original input data are very noisy, impairing obtaining the derivative due to the amplification of high frequency noise and, consequently, impairing the filtering method. The inverse method stands out for allowing the search for more elaborate solutions than a simple derivative, such as a global solution by a strictly increasing function, obtaining the final model from raw data, multi-well resolution and/or solutions that involve adjusting different types of curves, such as, for example, density and apparent velocity. A workflow using inversion or filtering solutions as a user input can save time and make it easier to obtain the final flow model.

Variations of the method proposed herein are possible without departing from the scope of the present invention. For example, an approach in which the solution is obtained from the raw data would be possible by performing a pre-processing internally, generating from the n curves of FIG. 3 a single accumulated velocity curve and, thus, coupling the same to the methodology proposed herein. In this case, the “d” and the “f(p)” in the objective function would be the same.

Another way to do this would be to look for a model that fits the curves in FIG. 3 in a decoupled way. For this to be possible, we should calculate from the interval flow model the revolutions per second (rps) of the spinner for each ascent and descent with different cable speed, V_{cabo}. This is possible if we admit the spinner characteristics as known and assume the threshold and slope of FIG. 3 as known. In summary: from the interval flow rate model, a graph like the one in FIG. 3 is determined for each depth, taking V_{cabo}, threshold, and slope as known, through which the rps curves are determined.

In practice, the models would be the same as those presented herein, changing only that the “d” of the objective function would be the decoupled rps curves and the “f (p)” would calculate the decoupled curves from the interval model.

Further, it is possible to include other regularizations in the objective function and other data that are related to the flow rate response. For example, using the other profiles that are run with the PLT, such as density. For this to be valid, it is enough to obtain a rps function that takes this data into account. In this case, the density would also be an adjustment data of the objective function.

As mentioned earlier, although aspects of the present disclosure may be susceptible to various modifications and alternative forms, specific embodiments have been shown by way of example in the drawings and have been described in detail in this document. But it should be understood that the invention is not intended to be limited to the particular disclosed forms. Rather, the present invention should encompass all modifications, equivalents and alternatives, which fall within its scope, as defined by the attached claims below.

1-5. (canceled)

6. A method for determining a final flow rate model, the method comprising:
a. inserting a spinner into a well, the spinner comprising one or more sensors;
b. generating a plurality of spinner data comprising one or more of:
a spinner rotational velocity at a given depth; and
an apparent flow velocity of a fluid in the well at a given depth;
c. generating, via an integral equation, a total flow rate of the fluid in the well based on the spinner data;
d. calculating an objective function of the integral equation, through the following equation:
θ∥d-ƒ(p)∥²+w∥ĉp∥²
wherein, (θ) is the objective function, (d) is the spinner data, f(p) is the interval flow rate, (σp) is a smoothness regularization of the spinner data, and (w) is a weight between a data adjustment and the smoothness regularization;
f. defining at least one convergence criterion;
g. adapting the integral equation based on an optimization method;
h. calculating a new objective function based on the adapted integral equation;
i. determining whether the at least one convergence criterion has been met, and repeating steps g-i if the at least one convergence criterion is not met; and
j. obtaining a final flow rate model.

7. The method of claim 6, wherein the smoothness regulation comprises a plurality of data adjustment parameters corresponding to a plurality of depths.

8. The method of claim 6, wherein the optimization method comprises one of a Gradient Descent method, a Gauss-Newton method, or a Levenberg-Marquardt method.

9. The method of claim 6, wherein the at least one convergence criterion comprises one or more of a number of data points, a convergence in the smoothness regularization, and an error in the model.

10. The method of claim 6, wherein a spatial discretization of the objective function is greater than the frequency of the generated spinner data.
